(19) United States
(12) Patent Application Publication
(10) Pub. No.: US 2020/0339011 A1
(43) Pub. Date: Oct. 29, 2020

(54) COMPONENT AND METHOD FOR IDENTIFYING AN OCCUPANT CONTACT OF A COMPONENT

(71) Applicants: VOLKSWAGEN AG, Wolfsburg (DE); GE-T GMBH, Ingolstadt (DE)

(72) Inventors: Christoph BOESE, Wolfenbüttel (DE); Patrick NICKEL, Lauta (DE); Roland OTTE, Osloss (DE); Nils QUANDER, Braunschweig (DE); Markus KNOBLOCH, Sassenburg (DE); Kim Alexander KUJELIS, Kõnigslutter (DE)

(21) Appl. No.: 16/764,862

(22) PCT Filed: Nov. 13, 2018
(86) PCT No.: PCT/EP2018/081065

§ 371 Date: May 17, 2020

(30) Foreign Application Priority Data
Nov. 17, 2017 (DE) 10 2017 220 540.7

(51) Int. Cl. B60N 2/00; B60N 2/56; B60N 2/75; B60N 3/04; B62D 1/06; H03K 17/955; H05B 1/02

(52) U.S. Cl. CPC B60N 2/002; B60N 2/5685; B60N 2/797; H05B 1/0238; B62D 1/06; H03K 17/955; H05B 1/0236; B60N 3/04

(57) ABSTRACT

A component with an integrated occupant contact identification and a heating function having at least one evaluation and control unit and at least two electrical conductors, which are powered independently of one another and which are assigned to various regions of the component, wherein the evaluation and control unit spatially detects an occupant contact of the component by evaluating a change in capacitance of the electrical conductors, wherein the evaluation and control unit increases the electric energy in the assigned electrical conductor based on a detected occupant contact. A method for identifying an occupant contact of a component.

### PRIORITY CLAIM

This patent application is a U.S. National Phase of International Patent Application No. PCT/EP2018/081065, filed 13 Nov. 2018, which claims priority to German Patent Application No. 10 2017 220 540.7, filed 17 Nov. 2017, the disclosures of which are incorporated herein by reference in their entireties.

### SUMMARY

Illustrative embodiments relate to a component with integrated occupant contact identification and heating function and a method for identifying occupant contact with a component.

### BRIEF DESCRIPTION OF THE DRAWINGS

Disclosed embodiments are explained in more detail below with reference to the drawings, in which:

FIG. 1 shows a schematic circuit arrangement for occupant contact identification and a heating function;

FIG. 2 shows an illustration of a steering wheel;

FIG. 3 shows a sectional illustration through a steering ring;

FIG. 4 shows a further illustration of a steering wheel; and

FIG. 5 shows an illustration of a PWM signal.

### DETAILED DESCRIPTION

Various components which have occupant contact identification are known. By way of example, transportation vehicle seats with seat occupant contact sensors are known. Furthermore known are steering wheels with so-called hands-off detection, i.e., to detect whether the hands of the driver of the transportation vehicle are on the steering wheel. This also constitutes occupant contact identification, namely identifying whether the hands of an occupant are in contact with the steering wheel.

DE 203 09 603 U1 discloses a generic component, such as a steering device for a transportation vehicle, with at least one actuating portion for actuating the steering device and a sensor device for detecting actuation of the steering device, wherein the sensor device is formed by at least one capacitive sensor element. In this case, it is further provided that the sensor device is formed by at least one electric conductor arrangement provided on the actuating portion of the steering device. In this case, at least two separate sensor elements can also be provided, which are each associated with different regions of the actuating portion of the steering device so that spatially-resolved occupant contact can be detected. Finally, it is further proposed that the sensor elements simultaneously serve as heating elements.

Disclosed embodiments are based on the technical problem of further improving a component with integrated occupant contact identification and heating function and a method for identifying occupant contact with a component.

The solution to the technical problem is realized by a component and a method.

To this end, the component with integrated occupant contact identification and heating function comprises at least one evaluation and control unit and at least two electric conductors, which can be powered independently of one another and which are associated with different regions of the component. In this case, the evaluation and control unit is designed such as to detect occupant contact with the component in a spatially resolved manner by evaluating a capacitive change in the electric conductors, wherein the electric energy in the associated electric conductor is increased subject to detected occupant contact. It is thus possible to specifically heat only that region for which occupant contact has been detected, so that the electric energy consumption can be noticeably reduced without a decline in comfort. There is therefore a first operating mode, which senses occupant contact, and a second operating mode, in which heating takes place. Both operating modes can also be implemented in parallel. The increase in energy also means that the time-averaged electric output is increased. The increase in the electric energy can take place, for example, as a result of an increase in the voltage or the current. However, the signal to the electric conductors may be a PWM signal, wherein the evaluation and control unit is designed such as to adapt the pulse-in to pulse-out ratio to increase the electric energy.

In at least one disclosed embodiment, it is provided that the PWM signal alternately consists of at least one measurement signal for detecting occupant contact with the component and a signal for implementing the heating function. In this case, it can also be provided that, if occupant contact has been detected for the first time following a plurality of measurement signals for occupant contact detection, a signal for implementing the heating function and a measurement signal for detecting occupant contact are then generated alternately.

In a further disclosed embodiment, the evaluation and control unit is designed such that the heating function can be deactivated and/or a heating function for the entire component can be adjusted. For example, the deactivation or the heating function for the entire component can take place as a result of user input. Alternatively or additionally, the adjustment can also take place automatically subject to the data of a temperature sensor, so that the heating function is deactivated at temperatures above a first limit value, for example, and/or the entire component is heated at a temperature below a second limit value. It is further possible to adjust the electric energy used for heating subject to temperature so that heating takes place with more energy at low temperatures, for example. In this case, the temperature can be an external temperature or a temperature inside a transportation vehicle.

Alternatively or additionally, at least one temperature sensor or a method or mechanism for estimating the temperature can be installed in the component to detect the temperature reached during heating so as to restrict or switch off the heating function, for example, if a certain temperature is reached. In this case, a separate temperature sensor is associated with each region with an electric conductor.

In a further disclosed embodiment, the component has a decoupling circuit, which decouples the measurement path for the capacitance change from the voltage supply in terms of signaling. The decoupling circuit is designed, for example, as a filter circuit and prevents disruptive capacitive influences.

In a further disclosed embodiment, the evaluation and control unit is connected to a reference electrode, which provides a defined opposing field to the electric conductors. The reference electrode is, for example, a copper plate, i.e., a capacitance change is determined between the electric conductor and the reference electrode.

In a further disclosed embodiment, the component is a steering wheel or a transportation vehicle seat or an armrest or a foot mat.

In terms of the configuration of the method, reference is made in full to the explanations above.

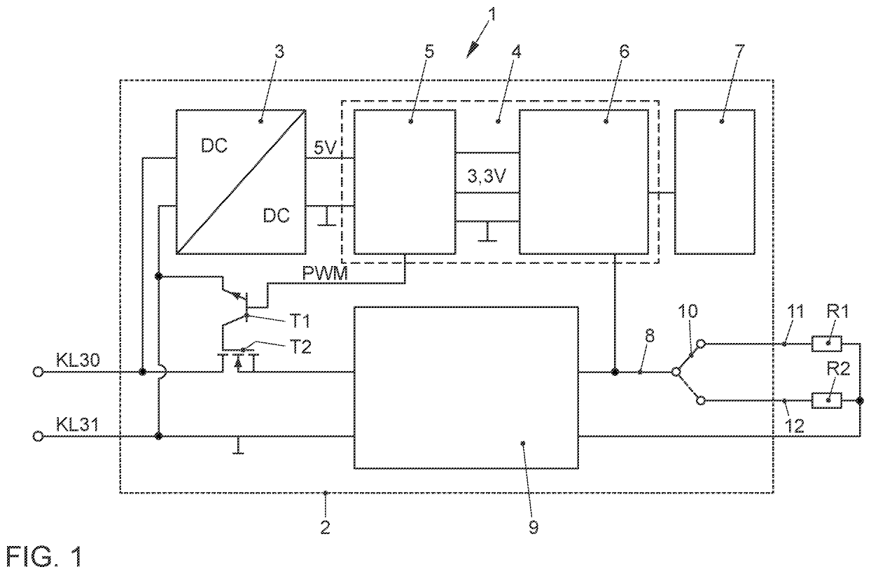

FIG. 1 shows a circuit arrangement for detecting occupant contact with a component, wherein most of the elements are arranged on a printed circuit board 2. The circuit arrangement 1 has two voltage connections KL30, KL31, which are connected to a battery (not illustrated). The circuit arrangement 1 further has a DC-DC converter 3, by which the battery voltage can be converted into an operating voltage for an evaluation and control unit 4. In the illustrated exemplary embodiment, the evaluation and control unit 4 comprises a microprocessor 5 and a measurement chip 6. The measurement chip 6 is connected to a reference electrode 7 and at least one electric line 8. A decoupling circuit 9 is furthermore arranged between the voltage connections KL30, KL31 and the line 8. The line 8 can be optionally connected via a switch element 10 to a first electric line 11 or a second electric line 12, which each have an ohmic resistance which is symbolized by the illustrated resistances R1, R2. The first electric line 11 and the second electric line 12 are installed in different regions of the component, which will be explained in more detail below. It should be noted here that the number of electric lines 11, 12 can also be greater. It should furthermore be noted that, as an alternative to the switch element 10, provision can also be made for the electric lines 11, 12 to also be operated simultaneously in parallel.

The evaluation and control unit 4 now generates a PWM control signal, which is then converted into a PWM signal, for example, by two transistors T1, T2. The evaluation and control unit 4 then controls the switch element 10, for example, such that the first electric line 11 is connected to the line 8, wherein a capacitance or capacitance change is measured by the evaluation and control unit 4. If the component is a steering wheel, for example, the capacitance changes when a hand is placed on the region of the first electric line 11. If such occupant contact is detected, a heating function is implemented in that the pulse-in time is extended. This method is then repeated with the second electric line 12. It is therefore possible to firstly specifically sense if and where there is occupant contact with the component and then specifically heat only the region in which occupant contact takes place. The sensor technology is then used to repeatedly detect changes in the occupant contact on a periodic basis.

In this case, the evaluation and control unit 4 can be designed such that the heating function can be deactivated, for example, because the user does not wish to use the function or because external conditions contradict it (external temperatures exceed a first limit or threshold value).

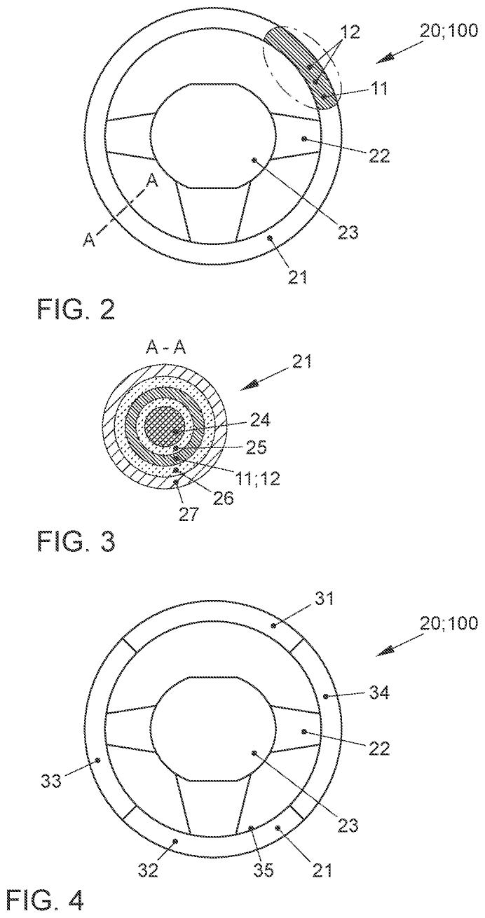

FIG. 2 shows a steering wheel 20 as a component 100. The steering wheel 20 has a steering ring 21, steering wheel spokes 22 and a center region 23, wherein the electric conductors 11, 12 (see FIG. 1) are arranged in the steering ring 21 and the circuit arrangement 1 is arranged in the center region 23, wherein, for illustrative purposes, part of the covering of the steering ring 21 has been removed so that the electric conductors 11, 12 are visible.

FIG. 3 shows a sectional illustration through the steering ring 21 along the section line A-A. A frame 24 is present in the center, on which a first foam layer 25 is arranged, on which the electric conductors 11, 12 are then arranged. In this case, the electric conductors 11, 12 can be arranged on a flexible substrate, for example, textile. An optional second foam layer 26 is then arranged around the electric conductors 11, and a leather layer 27 over this foam layer.

FIG. 4 shows a further steering wheel 20 as a component 100. In this case, the steering wheel 20 has five electric conductors, which are associated with five regions 31-35. In simple terms, the regions 31-35 are located at the top, at the bottom, on the left, on the right and on the inner side, wherein the electric conductor for the region 35 may extend over the entire circumference. In particular, a grip around the steering wheel 20 can be detected by the inner conductor.

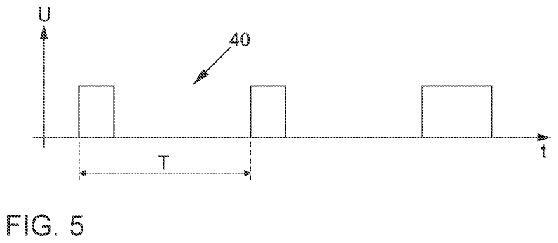

Finally, FIG. 5 shows, by way of example, a PWM signal 40 which has a duration T. In this case, the voltage U is represented over time t. In this case, the two first PWM signals are measurement signals to detect occupant contact with a component 100, wherein, in the case of the third signal, the pulse-in time is extended to implement the heating function after occupant contact is detected. In this case, the PWM signal can also have another form. The critical factor for the heating function is simply that the ratio of the pulse-in to pulse-out time is extended.

1. A component with integrated occupant contact identification and heating function, the component comprising:
at least one evaluation and control unit; and
at least two electric conductors, which are powered independently of one another and which are associated with different regions of the component,
wherein the evaluation and control unit spatially detects occupant contact with the component by evaluating a capacitive change in the at least two electric conductors, and
wherein the evaluation and control unit increases the electric energy in the associated electric conductor subject to detected occupant contact.

2. The component of claim 1, wherein the signal to the electric conductors is a PWM signal, and wherein the evaluation and control unit adapt the pulse-in to pulse-out ratio to increase the electric energy.

3. The component of claim 2, wherein the PWM signal alternately consists of at least one measurement signal for detecting occupant contact with the component and a signal for implementing the heating function.

4. The component of claim 1, wherein the heating function of the evaluation and control unit is deactivated and/or a heating function for the entire component is adjusted.

5. The component of claim 1, further comprising a decoupling circuit.

6. The component of claim 1, wherein the evaluation and control unit is connected to a reference electrode.

7. The component of claim 1, wherein the component is a steering wheel, vehicle seat, armrest or foot mat.

8. A method for identifying occupant contact with a component by at least one evaluation and control unit and at least two electric conductors, which are powered independently of one another and are associated with different regions of the component, wherein the method comprises:
the evaluation and control unit spatially detecting occupant contact with the component by evaluating a capacitive change in the electric conductors; and
the evaluation and control unit increaseing the electric energy in the associated electric conductor subject to detected occupant contact.

9. The method of claim 8, wherein the signal to the electric conductors is a PWM signal, and wherein the evaluation and control unit adapts the pulse-in to pulse-out ratio to increase the electric energy.

10. The method of claim 9, wherein the PWM signal alternately consists of at least one measurement signal for detecting occupant contact with the component and a signal for implementing the heating function.

11. The method of claim 8, wherein the heating function of the evaluation and control unit is deactivated and/or a heating function for the entire component is adjusted.

12. The method of claim 8, wherein the component further comprises a decoupling circuit.

13. The method of claim 8, wherein the evaluation and control unit is connected to a reference electrode.

14. The method of claim 8, wherein the component is a steering wheel, vehicle seat, armrest or foot mat.
